(19) United States
(12) Patent Application Publication
(10) Pub. No.: US 2011/0266314 A1
(43) Pub. Date: Nov. 3, 2011

(54) HIGH-PERFORMANCE PORTABLE ELECTRONIC SYSTEM AND METHODS

(76) Inventor: Lawrence R. Sommers, Morro Bay, CA (US)

(21) Appl. No.: 12/771,866

(22) Filed: Apr. 30, 2010

(51) Int. Cl. A44C 5/00; H05K 13/00; A45F 5/00

(52) U.S. Cl. 224/164; 224/191; 29/592.1

(57) ABSTRACT

A high-performance portable electronic system and its methods, involving portable electronic device and a compartment member for accommodating the portable electronic device, wherein the compartment member is removably installable into a sport element selected from a group consisting essentially of a sporting good and a sport garment, the sporting element having a surface, wherein the portable electronic device is removably installable in the compartment member, and wherein the portable electronic device and the compartment member, together, are contiguous with the surface.

### BACKGROUND OF THE INVENTION

1. Field of the Invention

The present invention generally relates to electronic systems and methods. More specifically, the present invention generally relates to portable electronic systems and methods for sports. Even more specifically, the present invention generally relates to high-performance electronic systems and methods for extreme sports.

2. Discussion of the Related Art

In the related art, devices, such as chronometers, have been used since ancient time. An example of a primitive device, e.g., a primitive chronometer, would be the sundial. In modern times, chronometers include mechanical, and digital, watches and clocks. Modern watches are typically fabricated either as wristwatches or pocket watches, both types of which have inherent physical limitations for the purpose of engaging in sports. Some wristwatches are waterproof and shockproof, but nevertheless, must be wrapped around a user's wrist, thereby encumbering the user in engaging in extreme sports.

### SUMMARY OF THE INVENTION

Several embodiments of the invention advantageously address the needs above as well as other needs by providing an electronic system that is handy, portable, high-performance, and conducive to easy removable installation into a sport element, such as a sporting good or sports garment, especially for extreme sports, and its related methods.

In one embodiment, the invention can be characterized as a high-performance portable electronic system comprising a portable electronic device and a compartment member for accommodating the portable electronic device, wherein the compartment member is removably installable into a sport element, such as a sporting good and a sport garment, the sporting element having a surface, wherein the portable electronic device is removably installable in the compartment member, and wherein the portable electronic device and the compartment member, together, are contiguous with the surface.

In an alternative embodiment, the invention can be characterized as a method of fabricating a high-performance portable electronic system comprising providing a portable electronic device and providing a compartment member for accommodating the portable electronic device, wherein the compartment member providing step comprises providing the compartment member as being removably installable into a sport element, such as a sporting good and a sport garment, the sporting element having a surface, wherein the portable electronic device providing step comprises providing the portable electronic device as being removably installable in the compartment member, and wherein the portable electronic device providing step and the compartment member providing step, together, comprise providing the portable electronic device and providing the compartment member as being contiguously disposable with the surface.

In yet another embodiment, the invention can be characterized as a method of using a high-performance portable electronic system generally comprising providing a high-performance portable electronic system, the high-performance portable electronic system providing step comprising providing a portable electronic device and providing a compartment member for accommodating the portable electronic device, wherein the compartment member providing step comprises providing the compartment member as being removably installable into a sport element, such as a sporting good and a sport garment, the sporting element having a surface, wherein the portable electronic device providing step comprises providing the portable electronic device as being removably installable in the compartment member, and wherein the portable electronic device providing step and the compartment member providing step, together, comprise providing the portable electronic device and providing the compartment member as being contiguously disposable with the surface, and disposing the portable electronic device in the compartment member.

### BRIEF DESCRIPTION OF THE DRAWINGS

The above and other aspects, features and advantages of several embodiments of the present invention will be more apparent from the following more particular description thereof, presented in conjunction with the following drawings.

FIG. 1 is a sectional view diagram of a portable electronic device and a compartment member in a high-performance portable electronic system as installed in a sport element, such as a surfboard, in accordance with an embodiment of the present invention.

FIG. 2 is a plan view diagram of a portable electronic device and a compartment member in a high-performance portable electronic system as installed in a sport element, such as a surfboard, in accordance with an embodiment of the present invention.

FIG. 3 is a plan view diagram of a portable electronic device and a compartment member in a high-performance portable electronic system as installed in a sport element, such as a kayak, in accordance with an alternative embodiment of the present invention.

FIG. 4 is a front view diagram of a portable electronic device and a compartment member in a high-performance portable electronic system as installed in a sport element, such as a snowboard jacket, in accordance with another embodiment of the present invention.

FIG. 5 is a perspective view diagram of a portable electronic device in a high-performance portable electronic system, in accordance with a general embodiment of the present invention.

FIG. 6 is a perspective view diagram of a compartment member in a high-performance portable electronic system, in accordance with a general embodiment of the present invention.

FIG. 7 is a perspective view diagram of a cover member in a high-performance portable electronic system, in accordance with a general embodiment of the present invention.

FIG. 8 is a perspective view diagram of a watchband in a high-performance portable electronic system, in accordance with a general embodiment of the present invention.

FIG. 9 is a frontal view diagram of the portable electronic device in the high-performance portable electronic system, in accordance with the embodiment of the present invention as shown in FIG. 5.

FIG. 10 is a side view diagram of the portable electronic device in the high-performance portable electronic system, in accordance with the embodiment of the present invention as shown in FIG. 5.

FIG. 11 is a plan view diagram of the compartment member in the high-performance portable electronic system, in accordance with the embodiment of the present invention as shown in FIG. 6.

FIG. 12 is a side view diagram of the compartment member in the high-performance portable electronic system, in accordance with the embodiment of the present invention as shown in FIG. 6.

FIG. 13 is a flowchart of a method for fabricating a high-performance portable electronic system, in accordance with another embodiment of the present invention.

FIG. 14 is a flowchart of a method for providing a compartment member in a high-performance portable electronic system, in accordance with an alternative embodiment of the present invention.

FIG. 15 is a flowchart of a method for using a high-performance portable electronic system, in accordance with another alternative embodiment of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of fasteners and mounting brackets, etc., to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

Some embodiments of the present invention generally involve a high-performance portable electronic system, generally comprising a portable electronic device, a compartment member for accommodating the portable electronic device, the compartment member being installable into a sport element, and a cover member for closing the compartment member.

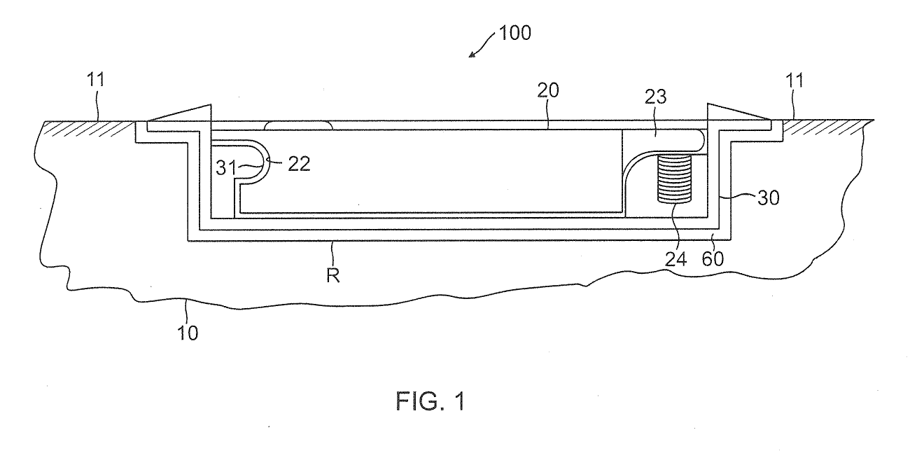

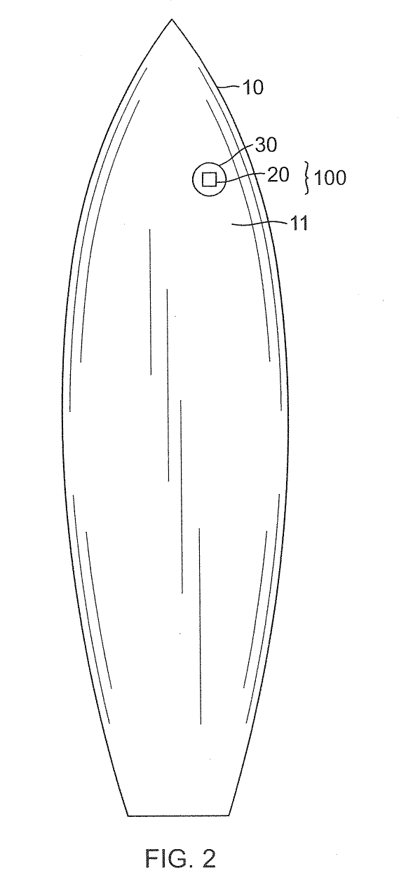

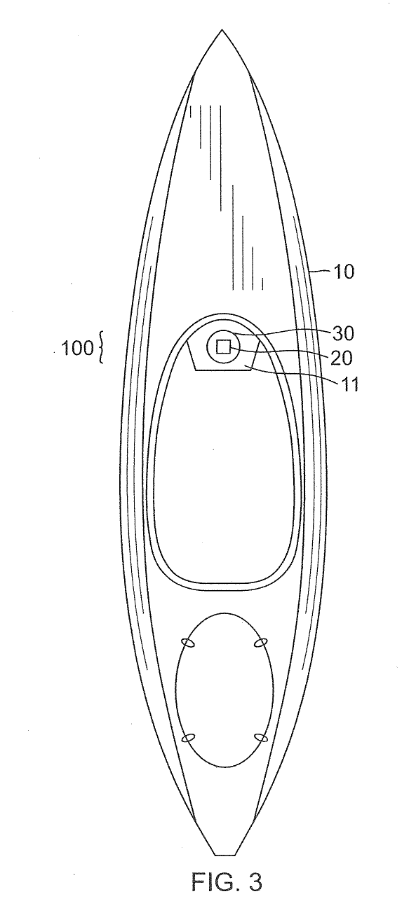

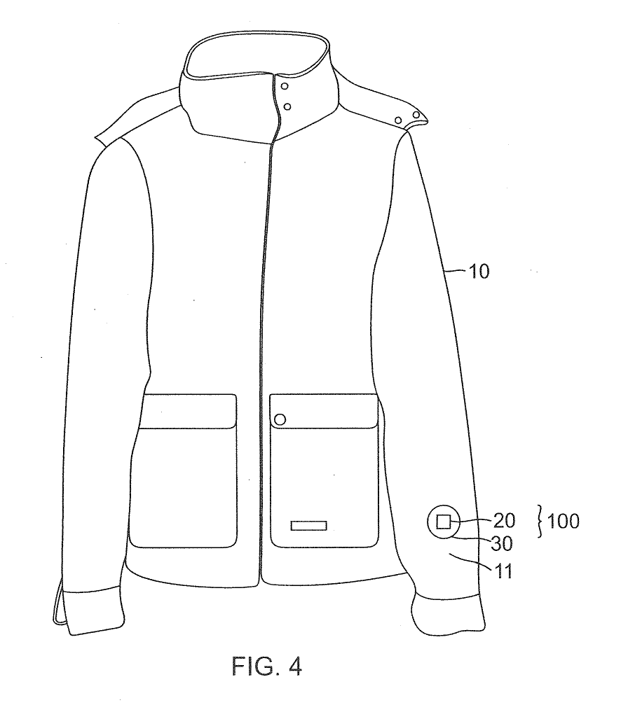

Referring first to FIG. 1, this sectional view diagram illustrates a portable electronic device 20 and a compartment member 30 of a high-performance portable electronic system 100 as installed in a sport element 10, in accordance with an embodiment of the present invention, by example only. The sport element 10 comprises an element, such as a sporting good and a sport garment. The sporting good comprises an element, such as a surfboard, a boogie board, a snow board, a skateboard, a sled, a kayak, a canoe, a bicycle, a stand-up paddle board, a gun stock, and a kite board, as well as their accessories, for example (FIGS. 2 and 3). The sport garment comprises an element, such as a snowboard jacket, a ski jacket, and a wetsuit, for example (FIG. 4). The sport element 10 comprises a surface 11 in which a recess R may be formed. The high-performance portable electronic system 100 generally comprises a portable electronic device 20, a compartment member 30 for accommodating the portable electronic device 20, the compartment member 30 being installable into a sport element 10, and a cover member 40 (FIG. 7) for closing the compartment member 30. The high-performance portable electronic system 100 further comprises a cured polymeric material 60 disposed between the sport element 10 and the compartment member 30. The portable electronic device 20 comprises a groove portion 22 and a mounting feature 23; and the compartment member 30 comprises a tongue portion 31 and a mounting portion 33. Alternatively, the portable electronic device 20 may comprise a tongue portion (not shown); and the compartment member 30 may comprise a groove portion (not shown).

Still referring to FIG. 1, the compartment member 30 is installed in the recess R of the sport element 10 by way of the cured polymeric material 60. Further, the portable electronic device 20 is removably installed in the compartment member 30 by way of both a tongue-and-groove coupling via the tongue portion 31 of the compartment member 30 and the groove portion 22 of the portable electronic device 20 as well as a mounting feature-and-fastener coupling via the mounting feature 23 of the portable electronic device 20 and mounting feature 33 using the fastener 24. Alternatively, the portable electronic device 20 may be removably installed in the compartment member 30 by way of both a tongue-and-groove coupling via a tongue portion (not shown) of the portable electronic device 20 and a groove portion (not shown) of the compartment member 30 in conjunction with a mounting-feature-and-fastener coupling via the mounting feature 23 of the portable electronic device 20 and the mounting feature 33 of the compartment member 30 using the fastener 24. The portable electronic device 20 and the compartment member 30, together, are contiguous with the surface 11.

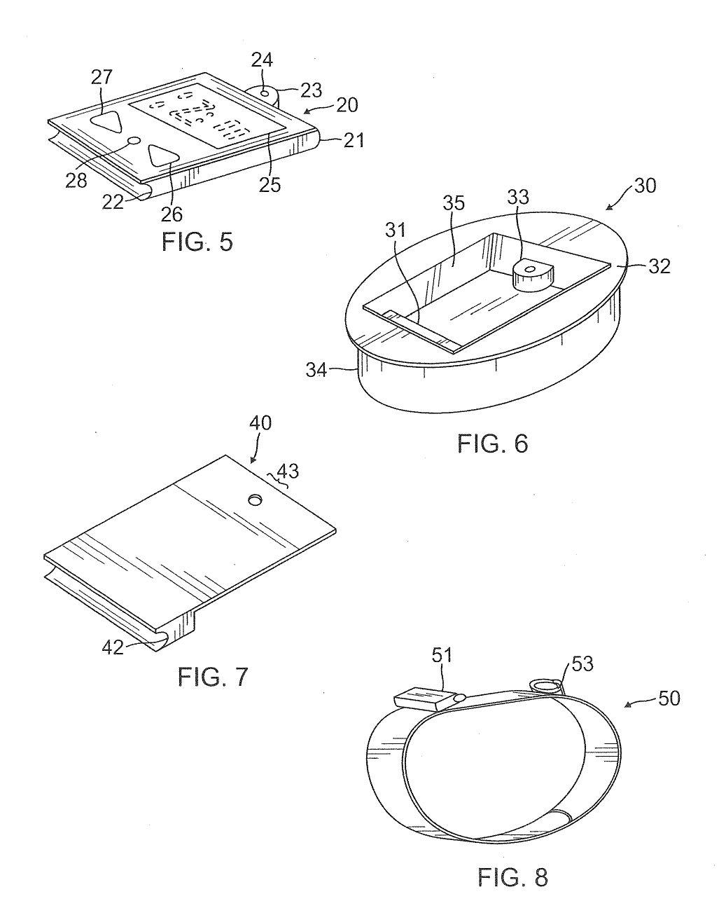

Still referring to FIG. 1, the portable electronic device 20 enhances the navigational and survival skills of the user (not shown) by providing features, as described in relation to FIG. 5, infra, that are handy and robust. The tongue-and-groove coupling facilitates disposing of the portable electronic device 20 in the compartment member 30 by providing easy alignment and registry while the mounting feature 23 and the fastener 24 facilitate removable coupling of the portable electronic device 20 with the compartment member 30. In addition, the tongue-and-groove coupling facilitates disposing the portable electronic device 20 in relation to the compartment member 30 such that these elements are disposed in a manner that is contiguous with the surface 11, wherein the user can receive the benefit of the features provided by the portable electronic device 20 with safety and without any mechanical interference with the act of engaging in a given sport.

Referring next to FIG. 2, this plan view diagram illustrates a portable electronic device 20 and a compartment member 30 of a high-performance portable electronic system 100 as installed in a sport element 10, the sport element 10 comprising a surfboard for example, in accordance with another embodiment of the present invention. The sport element comprises an element, such as a sporting good and a sport garment. The sport element 10 comprises a surface 11 in which a recess R may be formed (FIG. 1). The high-performance portable electronic system 100 generally comprises a portable electronic device 20, a compartment member 30 for accommodating the portable electronic device 20, the compartment member 30 being installable into a sport element 10, and a cover member 40 (FIG. 7) for closing the compartment member 30. The high-performance portable electronic system further comprises a cured polymeric material 60 disposed between the sport element 10 and the compartment member 30. The portable electronic device 20 comprises a groove portion 22 and a mounting feature 23; and the compartment member 30 comprises a tongue portion 31 and a mounting feature 33. Alternatively, the portable electronic device 20 comprises a tongue portion (not shown); and the compartment member 30 comprises a groove portion (not shown).

Still referring to FIG. 2, a recess R is formed in the sport element 10, e.g., the surfboard; and the compartment member 30 is installed in the recess of the sport element 10 by way of the cured polymeric material 60 (FIG. 1). Further, the portable electronic device 20 is removably installed in the compartment member 30 by way of both a tongue-and-groove coupling via the tongue portion 31 of the compartment member 30 and the groove portion 22 of the portable electronic device 20 as well as a mounting-feature-and-fastener coupling via the mounting feature 23 of the portable electronic device 20 and the mounting feature 33 of the compartment member 30 using the fastener 24 (FIG. 1). Alternatively, the portable electronic device 20 is removably installed in the compartment member 30 by way of both a tongue-and-groove coupling via a tongue (not shown) of the portable electronic device 20 and a groove (not shown) of the compartment member 30 as well as a mounting feature-and-fastener coupling via the mounting feature 23 of the portable electronic device 20 and the fastener 24. The portable electronic device 20 and the compartment member 30, together, are contiguous with the surface 11 (FIG. 1).

Still referring to FIG. 2, the portable electronic device 20 enhances the navigational and survival skills of the user, e.g., the surfer, by providing features, as described in relation to FIG. 5, infra, that are handy and robust. The tongue-and-groove coupling facilitates disposing of the portable electronic device 20 in the compartment member 30 by providing alignment and registry while the mounting feature 23 and the mounting feature 33 using the fastener 24 facilitate removable coupling of the portable electronic device 20 with the compartment member 30 (FIG. 1). In addition, the tongue-and-groove coupling facilitates disposing the portable electronic device 20 in relation to the compartment member 30 such that the portable electronic device 20 and the compartment member 30 are disposed in a manner that is contiguous with the surface 11, wherein the user, such as a surfer for example, can receive the benefit of the features provided by the portable electronic device 20 with safety and without any mechanical interference with the act of engaging in a given sport, e.g., surfing.

Referring next to FIG. 3, this plan view diagram illustrates a portable electronic device 20 and a compartment member 30 of a high-performance portable electronic system 100 as installed in a sport element 10, the sport element 10 comprising a kayak, in accordance with an embodiment of the present invention, by example only. The sport element comprises an element, such as a sporting good and a sport garment. The sport element 10 comprises a surface 11 in which a recess R may be formed (FIG. 1). The high-performance portable electronic system 100 generally comprises a portable electronic device 20, a compartment member 30 for accommodating the portable electronic device 20, the compartment member 30 being installable into a sport element 10, and a cover member 40 (FIG. 7) for closing the compartment member 30. The high-performance portable electronic system further comprises a cured polymeric material 60 disposed between the sport element 10 and the compartment member 30. The portable electronic device 20 comprises a groove portion 22 and a mounting feature 23; and the compartment member 30 comprises a tongue portion 31 and a mounting feature 33. Alternatively, the portable electronic device 20 comprises a tongue portion (not shown; and the compartment member 30 comprises a groove portion (not shown).

Still referring to FIG. 3, a recess R is formed in the sport element 10, e.g., the surfboard; and the compartment member 30 is installed in the recess of the sport element 10 by way of the cured polymeric material 60 (FIG. 1). Further, the portable electronic device 20 is removably installed in the compartment member 30 by way of both a tongue-and-groove coupling via the tongue portion 31 of the compartment member 30 and the groove portion 22 of the portable electronic device 20 as well as a mounting-feature-and-fastener coupling via the mounting feature 23 of the portable electronic device 20 and the mounting feature 33 of the compartment member 30 using the fastener 24 (FIG. 1). Alternatively, the portable electronic device 20 is removably installed in the compartment member 30 by way of both a tongue-and-groove coupling via a tongue (not shown) of the portable electronic device 20 and a groove (not shown) of the compartment member 30 as well as a mounting feature-and-fastener coupling via the mounting feature 23 of the portable electronic device 20 and the fastener 24. The portable electronic device 20 and the compartment member 30, together, are contiguous with the surface 11 (FIG. 1).

Still referring to FIG. 3, the portable electronic device 20 enhances the navigational and survival skills of the user, e.g., the kayaker, by providing features, as described in relation to FIG. 5, infra, that are handy and robust. The tongue-and-groove coupling facilitates disposing of the portable electronic device 20 in the compartment member 30 by providing alignment and registry while the mounting feature 23 and the mounting feature 33 using the fastener 24 facilitate removable coupling of the portable electronic device 20 with the compartment member 30 (FIG. 1). In addition, the tongue-and-groove coupling facilitates disposing the portable electronic device 20 in relation to the compartment member 30 such that the portable electronic device 20 and the compartment member 30 are disposed in a manner that is contiguous with the surface 11, wherein the user, such as a kayaker for example, can receive the benefit of the features provided by the portable electronic device 20 with safety and without any mechanical interference with the act of engaging in a given sport, e.g., kayaking.

Referring next to FIG. 4, this front view diagram illustrates a portable electronic device 20 and a compartment member 30 of a high-performance portable electronic system 100 as installed in a sport element 10, the sport element 10 comprising a snowboard jacket, in accordance with yet another embodiment of the present invention, by example only. The sport element comprises an element, such as a sporting good and a sport garment. The sport element 10 comprises a surface 11 in which a recess R may be formed (FIG. 1). The high-performance portable electronic system 100 generally comprises a portable electronic device 20, a compartment member 30 for accommodating the portable electronic device 20, the compartment member 30 being installable into a sport element 10, and a cover member 40 (FIG. 7) for closing the compartment member 30. The high-performance portable electronic system further comprises a cured polymeric material 60 disposed between the sport element 10 and the compartment member 30. The portable electronic device 20 comprises a groove portion 22 and a mounting feature 23; and the compartment member 30 comprises a tongue portion 31 and a mounting feature 33. Alternatively, the portable electronic device 20 comprises a tongue portion (not shown; and the compartment member 30 comprises a groove portion (not shown).

Still referring to FIG. 4, a recess R is formed in the sport element 10, e.g., the snowboard jacket; and the compartment member 30 is installed in the recess of the sport element 10 by way of the cured polymeric material 60 (FIG. 1). The recess may be formed in any part of the sport garment that is easily visible and accessible by the user, e.g., the snowboarder. Further, the portable electronic device 20 is removably installed in the compartment member 30 by way of both a tongue-and-groove coupling via the tongue portion 31 of the compartment member 30 and the groove portion 22 of the portable electronic device 20 as well as a mounting-feature-and-fastener coupling via the mounting feature 23 of the portable electronic device 20 and the mounting feature 33 of the compartment member 30 using the fastener 24 (FIG. 1). Alternatively, the portable electronic device 20 is removably installed in the compartment member 30 by way of both a tongue-and-groove coupling via a tongue (not shown) of the portable electronic device 20 and a groove (not shown) of the compartment member 30 as well as a mounting feature-and-fastener coupling via the mounting feature 23 of the portable electronic device 20 and the fastener 24. The portable electronic device 20 and the compartment member 30, together, are contiguous with the surface 11 (FIG. 1).

Still referring to FIG. 4, the portable electronic device 20 enhances the navigational and survival skills of the user, e.g., the snowboarder, by providing features, as described in relation to FIG. 5, infra, that are handy and robust. The tongue-and-groove coupling facilitates disposing of the portable electronic device 20 in the compartment member 30 by providing alignment and registry while the mounting feature 23 and the mounting feature 33 using the fastener 24 facilitate removable coupling of the portable electronic device 20 with the compartment member 30 (FIG. 1). In addition, the tongue-and-groove coupling facilitates disposing the portable electronic device 20 in relation to the compartment member 30 such that the portable electronic device 20 and the compartment member 30 are disposed in a manner that is contiguous with the surface 11, wherein the user, such as a snowboarder for example, can receive the benefit of the features provided by the portable electronic device 20 with safety and without any mechanical interference with the act of engaging in a given sport, e.g., snowboarding.

Referring next to FIG. 5, this perspective view diagram illustrates a portable electronic device 20 of a high-performance portable electronic system 100, in accordance with a general embodiment of the present invention. The portable electronic device 20 comprises a housing 21, electronic circuitry (not shown), and at least one battery (not shown), wherein the at least one battery may be replaceable or rechargeable. In addition, the portable electronic device 20 comprises at least one element, such as a high-end time-piece, a high-accuracy time-piece, an action sports time-piece, and an extreme sports time-piece. Further, the portable electronic device comprises at least one electronic feature, such as a water-proof feature, a shock-proof feature, a chronometer, an atomic clock, a liquid crystal display, a digital display, a tide chart, a global positioning system, a homing device, a spot locator, a spot satellite messenger, an electronic device operable in a breadcrumb tracking mode, an electronic compass, a mechanical compass, a stop-watch, an alarm feature, a calendar feature with a date display, a lighting feature, a wireless telecommunication device, a cellular phone, a digital pager, and a personal digital assistant. The portable electronic device 20 comprises at least one control feature, such as a touch-screen 25, touch pads 26, 27, a button 28, by example only, for operating the at least one electronic feature by way of the electronic circuitry. The portable electronic device 20 comprises a groove portion 22 and a mounting feature 23; and the compartment member 30 comprises a tongue portion 31 and a mounting feature 33. Alternatively, the portable electronic device 20 comprises a tongue portion (not shown); and the compartment member 30 comprises a groove portion (not shown).

Still referring to FIG. 5, the housing 21 of the portable electronic device 20 contains the at least one control feature, the electronic circuitry (not shown) and the at least one battery (not shown). The at least one control feature is in electronic communication with the electronic circuitry; and the electronic circuitry is powered by the at least one battery. The at least one electronic feature is controlled by the electronic circuitry. Any display features, e.g., a liquid crystal display and a digital display, may be used in conjunction with the touch screen. The portable electronic device 20 comprises a groove portion 22 that registers with the tongue portion 31 of the compartment member 30 and a mounting feature 23 that registers with mounting feature 33 of the compartment member 30. The mounting feature 23 and the mounting feature 33 each comprise a feature, such as a tap hole and a threaded hole for accommodating the fastener 24 which removably couples the portable electronic device 20 with the compartment member 30.

Still referring to FIG. 5, the portable electronic device 20 provides a user with at least one benefit, such as comfort, function, and mobility. The housing 21 may be water-proof and shock-proof for protecting the control features, any other electronic feature, the electronic circuitry (not shown) and the at least one battery (not shown) from the harsh environments that are typically experienced while engaging in sports, especially extreme sports. In operation, the display may optionally encompass a touch screen which would minimize or eliminate the possibility of water leakage into the portable electronic device 20. The portable electronic device 20 may be likewise coupled with a watchband 50 (FIG. 8) when not in use in conjunction with the sport element 10. The at least one control feature, such as a touch-screen 25, a touchpad 27, a button 28, by example only, operate the at least one electronic feature by way of the electronic circuitry.

Referring next to FIG. 6, this perspective view diagram illustrates a compartment member 30 of a high-performance portable electronic system 100, in accordance with a general embodiment of the present invention. The compartment member 30 comprises a tongue portion 31 or an optional groove portion (not shown), a lip 32, and a mounting feature 33, wherein the compartment member 30 comprises at least one feature, such as a beveled interior edge 35, a lower portion 34 conducive for anchoring in the sport element, a mounting feature 33 for accommodating a fastener 24, and a dimension in a range of approximately 2.5 inches to approximately 4 inches. The compartment member 30 also comprises at least one material, such as a polymeric material, a rigid plastic, a flexible plastic, a pliable plastic, an elastic polymer, a composite material, a metal, and a metal alloy, such as stainless steel.

Still referring to FIG. 6, the tongue portion 31 and the mounting feature 33 of the compartment member 30 respectively register with the groove portion 22 and the mounting feature 23 of the portable electronic device 20. The mounting feature 23 and the mounting feature 33 each comprise a feature, such as a tap hole and a threaded hole for accommodating the fastener 24 which removably couples the portable electronic device 20 with the compartment member 30. The compartment member 30 is installed in a recess R of the sport element 10 and affixed therein by way of a polymeric material, later becoming the cured polymeric material 60 (FIG. 1).

Still referring to FIG. 6, in operation, the compartment member 30 accommodates the portable electronic device 20 when in use and accommodates a cover member 40 (FIG. 7) when the portable electronic device 20 is not in use. The lower portion 34 functions as an anchor for the compartment member 30 in the sport element 10. The tongue portion 31 and the mounting feature 33 facilitate registration and disposition of both the portable electronic device 20 and the cover member 40 in a manner such that the portable electronic device 20 in conjunction with the compartment member 30, and the cover member 40 in conjunction with the compartment member 30, are contiguous with the surface 11 of the sport element, thereby providing safety to the user, and thereby eliminating interference with engagement of the sport. The lip 32 is flushly disposed in relation to the surface 11 or optionally makes a smooth transition thereto with a smooth gradient, e.g., a gradient having an angular range of approximately 0 degrees to approximately 45 degrees and a preferred angular range of approximately 0 degrees to approximately 25 degrees, for enhancing safety and non-interference of the high-performance portable electronic system 100.

Referring next to FIG. 7, this perspective view diagram illustrates a cover member 40 of a high-performance portable electronic system 100, in accordance with a general embodiment of the present invention. The cover member 40 comprises a groove portion 42 and a mounting feature 43, wherein the mounting feature 43 comprises a feature, such as a tap hole and a threaded hole. When the portable electronic device 20 is not in use, the cover member 40 and the compartment member 30, together, are contiguous with the surface 11. Also, the cover member 40 comprises at least one material, such as a polymeric material, a rigid plastic, a flexible plastic, a pliable plastic, an elastic polymer, a composite material, a metal, and a metal alloy, such as stainless steel.

Still referring to FIG. 7, the groove portion 42 of the cover member 40 is coupled with the tongue portion 31 of the compartment member 30 when the portable electronic device 20 is not in use. The cover member 40 is disposed in the compartment member 30 by way of registering the mounting portion 43 of the cover member with the mounting feature 33 of the compartment member and by registering the groove portion 42 with the tongue portion 31 of the compartment member 30, wherein the cover member 40 is removably coupled with the compartment member 30 by disposing a fastener through the tap hole or threaded hole.

Still referring to FIG. 7, the cover member 40 will function as a closure for the compartment member 30 when the portable electronic device 20 is not in use. The tongue portion 31 and the mounting feature 33 of the compartment member 30 acting respectively in conjunction with the groove portion 42 and the mounting feature 43 of the cover member 40 facilitate registration and disposition of the cover member 40 in a manner such that the cover member 40 in conjunction with the compartment member 30 are contiguous with the surface 11 of the sport element, thereby providing safety to the user, and thereby eliminating interference with engagement of the sport.

Referring next to FIG. 8, this perspective view diagram illustrates a watchband 50 of a high-performance portable electronic system 100, in accordance with yet another embodiment of the present invention. The watchband 50 comprises a tongue portion 51 and a mounting feature 53. The watchband 50 comprises any suitable structure for removably disposing the watchband around a user's wrist, e.g., a hook-and-loop fastener (such as Velcro®), a buckle, a clasp, a polymeric or plastic band, an elastic polymeric band, and a metal or metal alloy band, e.g., a metal link band and a stretch-link metal band. The watchband comprises at least one material, such as a polymer, polymeric material, a nylon, a polyethylene, a polypropylene, a polyester, a metal, and metal alloy, and a composite material. The mounting feature 53 comprises a tap hole or a threaded hole for accommodating the fastener 24.

Still referring to FIG. 8, the mounting feature 23 of the portable electronic device 20 is registered with the mounting feature 53 of the watchband 50; and the groove portion 22 of the electronic device 20 is registered with the tongue portion 51 of the watchband 50. The portable electronic device 20 is removably coupled with the watchband 50 by way of the fastener 24 being disposed through the mounting feature 23 and into the mounting feature 53. The watchband 50 is removably disposed around a user's wrist using any suitable structure, e.g., a hook-and-loop fastener (such as Velcro®), a buckle, a clasp, a polymeric or plastic band, an elastic polymeric band, and a metal or metal alloy band, e.g., a metal link band and a stretch-link metal band. The watchband 50 can also be removably disposed on a user's wrist by stretching it over the user's hand if it comprises an elastic material.

Still referring to FIG. 8, the watchband 50 accommodates the portable electronic device 20 on a user's wrist (not shown) when the portable electronic device 20 is not in use with the sport element 10. The watchband 50 is wrapped around a user's wrist (not shown) so that the user may still have all the electronic features of the portable electronic device 20 available even when not actually engaging in the sport.

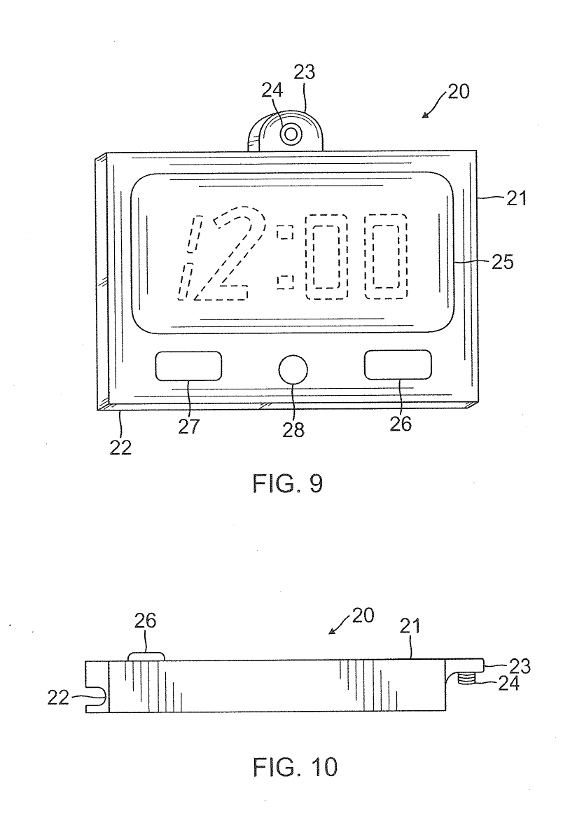

Referring next to FIG. 9, this front view diagram illustrates the portable electronic device 20 of the high-performance portable electronic system 100, in accordance with the embodiment of the present invention as shown in FIG. 5. The portable electronic device 20 comprises a housing 21, electronic circuitry (not shown), and at least one battery (not shown), wherein the at least one battery may be replaceable or rechargeable. In addition, the portable electronic device 20 comprises at least one element, such as a high-end time-piece, a high-accuracy time-piece, an action sports time-piece, and an extreme sports time-piece. Further, the portable electronic device 20 comprises at least one electronic feature, such as a water-proof feature, a shock-proof feature, a chronometer, an atomic clock, a liquid crystal display, a digital display, a tide chart, a global positioning system, a homing device, a spot locator, a spot satellite messenger, an electronic device operable in a breadcrumb tracking mode, an electronic compass, a mechanical compass, a stop-watch, an alarm feature, a calendar feature with a date display, a lighting feature, a wireless telecommunication device, a cellular phone, a digital pager, and a personal digital assistant. The portable electronic device comprises at least one control feature, such as a touch-screen 25, touch pads 26, 27, a button 28, by example only, for operating the at least one electronic feature by way of the electronic circuitry. The portable electronic device 20 comprises a groove portion 22 and a mounting feature 23; and the compartment member 30 comprises a tongue portion 31 and a mounting portion 33. Alternatively, the portable electronic device 20 may comprise a tongue (not shown); and the compartment member 30 may comprise a groove portion (not shown). The mounting feature 23 has a tap hole or a threaded hole formed therethrough for accommodating the fastener 24. The fastener 24 comprises at least one element, such as a screw, an Allen-head screw, a Phillips screw, a cap screw, a set screw, a thumb screw, a butterfly screw, a machine screw, a shoulder screw, a knurled head screw, a slotted knurled head screw, a square head set screw, and a socket head cap screw.

Still referring to FIG. 9, the housing 21 of the portable electronic device 20 contains the at least one control feature, the electronic circuitry (not shown) and the at least one battery (not shown). The at least one control feature is in electronic communication with the electronic circuitry; and the electronic circuitry is powered by the at least one battery. The at least one electronic feature is controlled by the electronic circuitry. Any display features, e.g., a liquid crystal display and a digital display, may be used in conjunction with the touch screen. The portable electronic device 20 comprises a groove portion 22 that registers with the tongue portion 31 of the compartment member 30 and a mounting feature 23 that registers with mounting feature 33 of the compartment member 30. The mounting feature 23 and the mounting feature 33 each comprises a tap hole or a threaded hole for accommodating the fastener 24 which removably couples the portable electronic device 20 with the compartment member 30.

Still referring to FIG. 9, the portable electronic device 20 provides a user with at least one benefit, such as comfort, function, and mobility. The housing 21 may be water-proof and shock-proof for protecting the control features, any other electronic feature, the electronic circuitry (not shown) and the at least one battery (not shown) from the harsh environments that are typically experienced while engaging in sports, especially extreme sports. In operation, the display may optionally encompass a touch screen which would minimize or eliminate the possibility of water leakage into the portable electronic device 20. The portable electronic device 20 may be likewise coupled with a watchband 50 (FIG. 8) when not in use in conjunction with the sport element 10. The at least one control feature, such as a touch-screen 25, a touchpad 27, a button 28, by example only, operate the at least one electronic feature by way of the electronic circuitry.

Referring next to FIG. 10, this side view diagram illustrates the portable electronic device 20 of the high-performance portable electronic system 100, in accordance with the embodiment of the present invention as shown in FIG. 5. The portable electronic device 20 comprises a housing 21, electronic circuitry (not shown), and at least one battery (not shown), wherein the at least one battery may be replaceable or rechargeable. In addition, the portable electronic device 20 comprises at least one element, such as a high-end time-piece, a high-accuracy time-piece, an action sports time-piece, and an extreme sports time-piece. Further, the portable electronic device 20 comprises at least one electronic feature, such as a water-proof feature, a shock-proof feature, a chronometer, an atomic clock, a liquid crystal display, a digital display, a tide chart, a global positioning system, a homing device, a spot locator, a spot satellite messenger, an electronic device operable in a breadcrumb tracking mode, an electronic compass, a mechanical compass, a stop-watch, an alarm feature, a calendar feature with a date display, a lighting feature, a wireless telecommunication device, a cellular phone, a digital pager, and a personal digital assistant. The portable electronic device comprises at least one control feature, such as a touch-screen 25, touch pads 26, 27, a button 28, by example only, for operating the at least one electronic feature by way of the electronic circuitry. The portable electronic device 20 comprises a groove portion 22 and a mounting feature 23; and the compartment member 30 comprises a tongue portion 31. Alternatively, the portable electronic device 20 may comprise a tongue portion (not shown); and the compartment member 30 may comprise a groove portion (not shown). The mounting feature 23 has a tap hole or a threaded hole formed therethrough for accommodating the fastener 24. The fastener 24 comprises at least one element, such as a screw, an Allen-head screw, a Phillips screw, a cap screw, a set screw, a thumb screw, a butterfly screw, a machine screw, a shoulder screw, a knurled head screw, a slotted knurled head screw, a square head set screw, and a socket head cap screw.

Still referring to FIG. 10, the housing 21 of the portable electronic device 20 contains the at least one control feature, the electronic circuitry (not shown) and the at least one battery (not shown). The at least one control feature is in electronic communication with the electronic circuitry; and the electronic circuitry is powered by the at least one battery. The at least one electronic feature is controlled by the electronic circuitry. Any display features, e.g., a liquid crystal display and a digital display, may be used in conjunction with the touch screen. The portable electronic device 20 comprises a groove portion 22 that registers with the tongue portion 31 of the compartment member 30 and a mounting feature 23 that registers with mounting feature 33 of the compartment member 30. The mounting feature 23 and the mounting feature 33 each comprise a feature, such as a tap hole and a threaded hole for accommodating the fastener 24 which removably couples the portable electronic device 20 with the compartment member 30.

Still referring to FIG. 10, the portable electronic device 20 provides a user with at least one benefit, such as comfort, function, and mobility. The housing 21 may be water-proof and shock-proof for protecting the control features, any other electronic feature, the electronic circuitry (not shown) and the at least one battery (not shown) from the harsh environments that are typically experienced while engaging in sports, especially extreme sports. In operation, the display may optionally encompass a touch screen which would minimize or eliminate the possibility of water leakage into the portable electronic device 20. The portable electronic device 20 may be likewise coupled with a watchband 50 (FIG. 8) when not in use in conjunction with the sport element 10. The at least one control feature, such as a touch-screen 25, a touchpad 27, a button 28, by example only, operate the at least one electronic feature by way of the electronic circuitry.

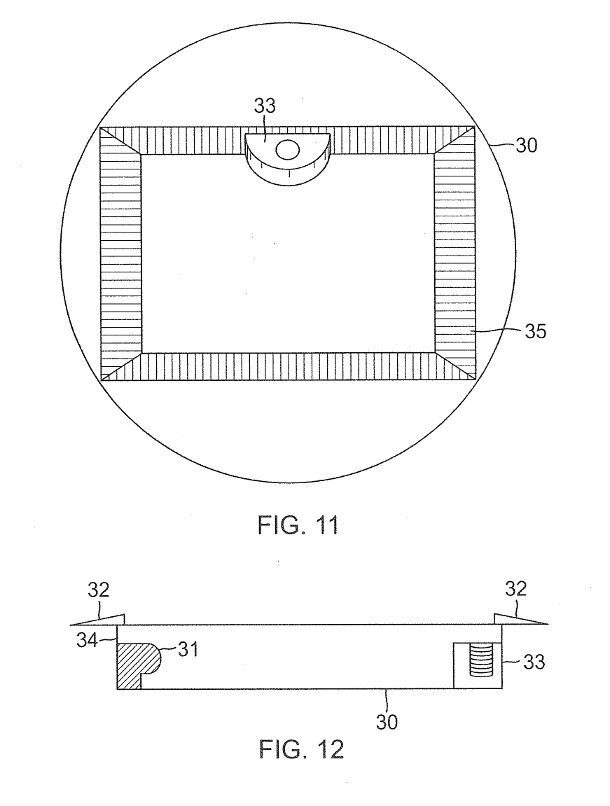

Referring next to FIG. 11, this plan view diagram illustrates the compartment member 30 of the high-performance portable electronic system 100, in accordance with the embodiment of the present invention as shown in FIG. 6. The compartment member 30 comprises a tongue portion 31 or an optional groove portion (not shown), a lip 32, and a mounting feature 33, wherein the compartment member 30 comprises at least one feature, such as a beveled interior edge 35, a lower portion 34 conducive for anchoring in the sport element, a mounting feature 33 for accommodating a fastener 24, and a dimension in a range of approximately 2.5 inches to approximately 4 inches. The compartment member 30 also comprises at least one material selected from a group consisting essentially of a polymeric material, a rigid plastic, a flexible plastic, a pliable plastic, an elastic polymer, a composite material, a metal, and a metal alloy, such as stainless steel. The compartment member comprises a dimension in a range of approximately 2.5 inches to approximately 4 inches.

Still referring to FIG. 11, the tongue portion 31 and the mounting feature 33 of the compartment member 30 respectively register with the groove portion 22 and the mounting feature 23 of the portable electronic device 20. The mounting feature 23 and the mounting feature 33 each comprise a feature, such as a tap hole and a threaded hole for accommodating the fastener 24 which removably couples the portable electronic device 20 with the compartment member 30. The compartment member 30 is installed in a recess of the sport element 10 by way of a cured polymeric material 60 (FIG. 1).

Still referring to FIG. 11, in operation, the compartment member 30 accommodates the portable electronic device 20 when in use and accommodates a cover member 40 (FIG. 7) when the portable electronic device 20 is not in use. The lower portion 34 functions as an anchor for the compartment member 30 in the sport element 10. A polymeric material, later becoming the polymeric material 60, facilitates installation of the compartment member 30 in the recess R (FIG. 1). The tongue portion 31 and the mounting feature 33 facilitate registration and disposition of both the portable electronic device 20 and the cover member 40 in a manner such that the portable electronic device 20 with the compartment member 30, and the cover member 40 with the compartment member 30, are contiguous with the surface 11 of the sport element, thereby providing safety to the user, and thereby eliminating interference with engagement of the sport. The lip 32 is flushly disposed in relation to the surface 11 or optionally makes a smooth transition thereto with a smooth gradient, e.g., a gradient having an angular range of approximately 0 degrees to approximately 45 degrees and a preferred angular range of approximately 0 degrees to approximately 25 degrees, for enhancing safety and non-interference of the high-performance portable electronic system 100.

Referring next to FIG. 12, this side view diagram illustrates the compartment member 30 of the high-performance portable electronic system 100, in accordance with the embodiment of the present invention as shown in FIG. 6. The compartment member 30 comprises a tongue portion 31 or an optional groove portion (not shown), a lip 32, and a mounting feature 33, wherein the compartment member 30 comprises at least one feature, such as a beveled interior edge 35, a lower portion 34 conducive for anchoring in the sport element, a mounting feature 33 for accommodating a fastener 24, and a dimension in a range of approximately 2.5 inches to approximately 4 inches. The compartment member 30 also comprises at least one material selected from a group consisting essentially of a polymeric material, a rigid plastic, a flexible plastic, a pliable plastic, an elastic polymer, a composite material, a metal, and a metal alloy, such as stainless steel. The compartment member comprises a dimension in a range of approximately 2.5 inches to approximately 4 inches.

Still referring to FIG. 12, the tongue portion 31 and the mounting feature 33 of the compartment member 30 respectively register with the groove portion 22 and the mounting feature 23 of the portable electronic device 20. The mounting feature 23 and the mounting feature 33 each comprise a feature, such as a tap hole and a threaded hole for accommodating the fastener 24 which removably couples the portable electronic device 20 with the compartment member 30. The compartment member 30 is installed in a recess of the sport element 10 by way of a polymeric material, later becoming the polymeric material 60 (FIG. 1).

Still referring to FIG. 12, in operation, the compartment member 30 accommodates the portable electronic device 20 when in use and accommodates a cover member 40 (FIG. 7) when the portable electronic device 20 is not in use. The lower portion 34 functions as an anchor for the compartment member 30 in the sport element 10. A polymeric material, later becoming the polymeric material 60, facilitates installation of the compartment member 30 in the recess R (FIG. 1). The tongue portion 31 and the mounting feature 33 facilitate registration and disposition of both the portable electronic device 20 and the cover member 40 in a manner such that the portable electronic device 20 with the compartment member 30, and the cover member 40 with the compartment member 30, are contiguous with the surface 11 of the sport element, thereby providing safety to the user, and thereby eliminating interference with engagement of the sport. The lip 32 is flushly disposed in relation to the surface 11 or optionally makes a smooth transition thereto with a smooth gradient, e.g., a gradient having an angular range of approximately 0 degrees to approximately 45 degrees and a preferred angular range of approximately 0 degrees to approximately 25 degrees, for enhancing safety and non-interference of the high-performance portable electronic system 100.

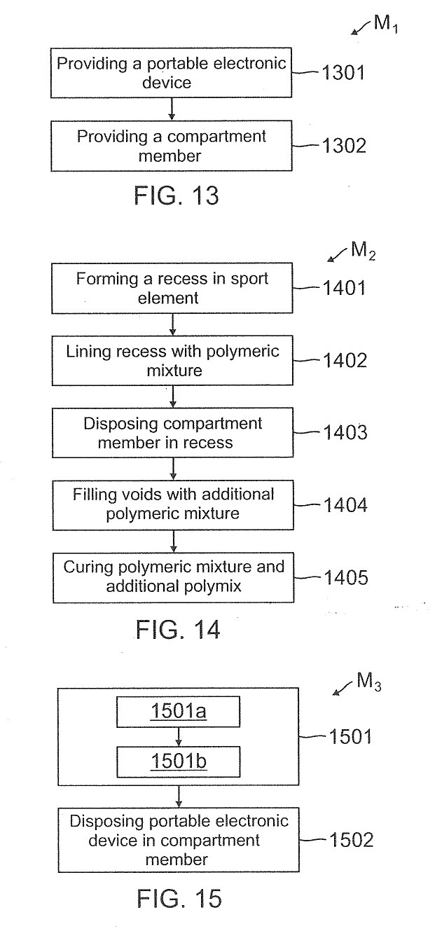

Referring next to FIG. 13, this flowchart illustrates a method M₁ of fabricating a high-performance portable electronic system, in accordance with an embodiment of the present invention. The method M₁ of fabricating a high-performance portable electronic system, comprising: providing a portable electronic device 20, as indicated by block 1301; and providing a compartment member 30 for accommodating the portable electronic device 20, as indicated by block 1302, wherein the compartment member 30 providing step comprises providing compartment member 30 as being removably installable into a sport element 10 selected from a group consisting essentially of a sporting good and a sport garment, the sporting element 10 having a surface 11, wherein the portable electronic device 20 providing step comprises providing the portable electronic device 20 as being removably installable in the compartment member 30, and wherein the portable electronic device 20 providing step and the compartment member 30 providing step, together, comprise providing the portable electronic device 20 and providing the compartment member 30 as being contiguously disposable with the surface 11.

Still referring to FIG. 13, the method M₁ further comprises providing a cover member 40 for closing the compartment member 30 when the portable electronic device 20 is removed from the compartment member 30 (not shown), wherein the cover member 40 providing step and the compartment member 30 providing step, together, comprise providing the cover member 40 and providing the compartment element 30 being contiguous with the surface 11.

Referring next to FIG. 14 and referring back to FIG. 13, this flowchart illustrates a method M₂ of providing a compartment member 30 in a high-performance portable electronic system, as indicated by block 1302 of FIG. 13, in accordance with an embodiment of the present invention. By example only, the compartment member 30 can be secured or “glassed” to an upper surface of the sport element 10, e.g., a surfboard. The method M₂ generally comprises the steps of: forming a recess in the sport element, as indicated by block 1401; lining the recess with a polymeric mixture (not shown), comprising at least one polymer, such as a resin, e.g., an epoxy resin, a polyamide, a polyimide, and a phenolic resin, as well as at least one inorganic material, such as glass hollow spheres, fiberglass fibers, glass fibers, and carbon fibers, as indicated by block 1402; disposing the compartment member 30 in the recess, as indicated by block 1403; filling any voids between the compartment member 30 and the sport element 10 with additional polymeric mixture to form a smooth transition from the upper surface of the surfboard to the upper surface of the compartment member 30, as indicated by block 1404; and curing the polymeric mixture and the additional polymeric mixture, thereby forming a smooth and hard interface between the compartment member and the sport element, as indicated by block 1405.

Referring finally to FIG. 15, this flowchart illustrates a method M₃ of using a high-performance portable electronic system, in accordance with an embodiment of the present invention. The method M₃ generally comprises providing a high-performance portable electronic system, as indicated by block 1501, the high-performance portable electronic system providing step comprising providing a portable electronic device 20, as indicated by block 1501a and providing a compartment member 30 for accommodating the portable electronic device 20, as indicated by block 1501b, wherein the compartment member 30 providing step comprises providing compartment member 30 as being removably installable into a sport element 10 selected from a group consisting essentially of a sporting good and a sport garment, the sporting element having a surface 11, wherein the portable electronic device 20 providing step comprises providing the portable electronic device 20 as being removably installable in the compartment member 30, and wherein the portable electronic device 20 providing step and the compartment member 30 providing step, together, comprise providing the portable electronic device 20 and providing the compartment member 30 as being contiguously disposable with the surface 11, and disposing the portable electronic device 20 in the compartment member 30, as indicated by block 1502.

Still referring to FIG. 15, the method M₃ further comprises providing a cover member 40 for closing the compartment member 30 when the portable electronic device 20 is removed from the compartment member 30 (not shown), wherein the cover member 40 providing step and the compartment member 30 providing step, together, comprise providing the cover member 40 and providing the compartment member 30 being contiguous with the surface 11; providing a watchband 50 (not shown); removing the portable electronic device 20 from the compartment member 30 (not shown); disposing the cover member 40 in the compartment member 30 (not shown); and coupling the portable electronic device 20 with the watchband 50 (not shown).

Information as herein shown and described in detail is fully capable of attaining the above-described object of the invention, the presently preferred embodiment of the invention, and is, thus, representative of the subject matter which is broadly contemplated by the present invention. The scope of the present invention fully encompasses other embodiments which may become obvious to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments that are known to those of ordinary skill in the art are hereby expressly incorporated by reference and are intended to be encompassed by the present claims.

Moreover, no requirement exists for a system or method to address each and every problem sought to be resolved by the present invention, for such to be encompassed by the present claims. Furthermore, no element, component, or method step in the present disclosure is intended to be dedicated to the public regardless of whether the element, component, or method step is explicitly recited in the claims. However, that various changes and modifications in form, material, and fabrication material detail may be made, without departing from the spirit and scope of the invention as set forth in the appended claims, should be readily apparent to those of ordinary skill in the art.

### INDUSTRIAL APPLICABILITY

The present invention generally industrially applies to electronic devices, systems, and methods. More specifically, the present invention generally industrially applies to portable electronic devices, systems, and methods for sports. Even more specifically, the present invention generally industrially applies to high-performance electronic devices, systems, and methods for extreme sports.

What is claimed:

1. A high-performance portable electronic system, comprising:
a portable electronic device; and
a compartment member for accommodating the portable electronic device,
wherein the compartment member is removably installable into a sport element selected from a group consisting essentially of a sporting good and a sport garment, the sport element having a surface,
wherein the portable electronic device is removably installable in the compartment member, and
wherein the portable electronic device and the compartment member, together, are contiguous with the surface.

2. The system of claim 1, further comprising a cover member for closing the compartment member when the portable electronic device is removed from the compartment member, wherein the cover member and the compartment member, together, are contiguous with the surface.

3. The system of claim 1,
wherein the sporting good comprises an element selected from a group consisting essentially of a surfboard, a boogie board, a snow board, a skateboard, a sled, a kayak, a canoe, a bicycle, a stand-up paddle board, a gun stock, a kite board, and any accessory thereto, and
wherein the sport garment comprises an element selected from a group consisting essentially of a wetsuit, a ski jacket, and a snowboard jacket.

4. The system of claim 1, wherein the compartment member comprises at least one material selected from a group consisting essentially of a polymeric material, a rigid plastic, a flexible plastic, a pliable plastic, an elastic polymer, a composite material, a metal, a metal alloy, and a stainless steel.

5. The system of claim 2, wherein the cover member comprises at least one material selected from a group consisting essentially of a polymeric material, a rigid plastic, a flexible plastic, a pliable plastic, an elastic polymer, a composite material, a metal, a metal alloy, and a stainless steel.

6. The system of claim 1,
wherein the portable electronic device provides a user with at least one benefit selected from a group consisting essentially of comfort, function, and mobility, and
wherein the portable electronic device comprises at least one element selected from a group consisting essentially of a high-end time-piece, a high-accuracy time-piece, an action sports time-piece, and an extreme sports time-piece.

7. The system of claim 1, wherein the portable electronic device comprises at least one electronic feature selected from a group consisting essentially of a water-proof feature, a shock-proof feature, a chronometer, an atomic clock, a liquid crystal display, a digital display, a tide chart, a global positioning system, a homing device, a spot locator, a spot satellite messenger, an electronic device operable in a breadcrumb tracking mode, an electronic compass, a mechanical compass, a stop-watch, an alarm feature, a calendar feature with a date display, a lighting feature, a wireless telecommunication device, a cellular phone, a digital pager, and a personal digital assistant.

8. The system of claim 1, further comprising at least one fastener,
wherein the portable electronic device and the compartment member each comprise a mounting feature having at least one accommodating feature selected from a group consisting essentially of a tap hole and a threaded hole, and
wherein the at least one fastener is disposable through the accommodating feature.

9. The system of claim 1, wherein the compartment member comprises at least one feature selected from a group consisting essentially of a beveled interior edge, a lower portion conducive for anchoring in the sport element, a mounting feature for accommodating a fastener, and a dimension in a range of approximately 2.5 inches to approximately 4 inches.

10. The system of claim 9, wherein the fastener comprises at least one element selected from a group consisting essentially of a screw, an Allen-head screw, a Phillips screw, a cap screw, a set screw, a thumb screw, a butterfly screw, a machine screw, a shoulder screw, a knurled head screw, a slotted knurled head screw, a square head set screw, and a socket head cap screw.

11. The system of claim 2,
wherein the compartment member comprises a tongue portion, and
wherein the cover member and the portable electronic device each comprise a groove portion for complementary coupling with the tongue portion.

12. The system of claim 2, further comprising a watchband for accommodating the portable electronic device on a user's wrist,
wherein the watchband comprises a tongue portion and
wherein the cover member and the portable electronic device each comprise a groove portion for complementary coupling with the tongue portion.

13. The system of claim 1, further comprising:
at least one fastener;
a cover member for closing the compartment member when the portable electronic device is removed from the compartment member, wherein the cover member and the compartment member, together, are contiguous with the surface; and
a watchband for accommodating the portable electronic device on a user's wrist,
wherein the compartment member comprises a tongue portion,
wherein the cover member and the portable electronic device each comprise a groove portion for complementary coupling with the tongue portion,
wherein the watchband comprises a tongue portion,
wherein the cover member and the portable electronic device each comprise a groove portion for complementary coupling with the tongue portion,
wherein the sporting good comprises an element selected from a group consisting essentially of a surfboard, a boogie board, a snow board, a skateboard, a sled, a kayak, a canoe, a bicycle, a stand-up paddle board, a gun stock, a kite board, and any accessory thereto,
wherein the sport garment comprises an element selected from a group consisting essentially of a wetsuit, a ski jacket, and a snowboard jacket,
wherein the portable electronic device provides a user with at least one benefit selected from a group consisting essentially of comfort, function, and mobility,
wherein the portable electronic device comprises at least one element selected from a group consisting essentially of a high-end time-piece, a high-accuracy time-piece, an action sports time-piece, and an extreme sports time-piece,
wherein the portable electronic device comprises at least one electronic feature selected from a group consisting essentially of a water-proof feature, a shock-proof feature, a chronometer, an atomic clock, a liquid crystal display, a digital display, a tide chart, a global positioning system, a homing device, a spot locator, a spot satellite messenger, an electronic device operable in a breadcrumb tracking mode, an electronic compass, a mechanical compass, a stop-watch, an alarm feature, a calendar feature with a date display, a lighting feature, a wireless telecommunication device, a cellular phone, a digital pager, and a personal digital assistant,
wherein the portable electronic device and the compartment member each comprise a mounting feature having at least one accommodating feature selected from a group consisting essentially of a tap hole and a threaded hole,
wherein the at least one fastener is disposable through the accommodating feature
wherein the compartment member comprises at least one feature selected from a group consisting essentially of a beveled interior edge, a lower portion conducive for anchoring in the sport element, a mounting feature for accommodating a fastener, and a dimension in a range of approximately 2.5 inches to approximately 4 inches, and
wherein the fastener comprises at least one element selected from a group consisting essentially of a screw, an Allen-head screw, a Phillips screw, a cap screw, a set screw, a thumb screw, a butterfly screw, a machine screw, a shoulder screw, a knurled head screw, a slotted knurled head screw, a square head set screw, and a socket head cap screw.

14. A method of fabricating a high-performance portable electronic system, comprising:
providing a portable electronic device; and
providing a compartment member for accommodating the portable electronic device,
wherein the compartment member providing step comprises providing compartment member as being removably installable into a sport element selected from a group consisting essentially of a sporting good and a sport garment, the sport element having a surface,
wherein the portable electronic device providing step comprises providing the portable electronic device as being removably installable in the compartment member, and
wherein the portable electronic device providing step and the compartment member providing step, together, comprise providing the portable electronic device and providing the compartment member as being contiguously disposable with the surface.

15. The system of claim 14, further comprising providing a cover member for closing the compartment member when the portable electronic device is removed from the compartment member, wherein the cover member providing step and the compartment member providing step, together, comprise providing the cover member and providing the compartment member being contiguous with the surface.

16. The method of claim 14, wherein the step of providing a compartment member comprises:
forming a recess in the sport element;
lining the recess with a polymeric mixture, the lining step comprising providing the polymeric mixture, the polymeric mixture providing step comprising:
providing at least one polymeric material selected from a group consisting essentially of a polymer, a resin, an epoxy resin, a polyamide, a polyimide, and a phenolic resin; and
providing at least one inorganic material selected from a group consisting essentially of a plurality of hollow glass spheres, a plurality of fiberglass fibers, a plurality of glass fibers, a plurality of carbon fiber, and a plurality of silicon carbide fibers;
disposing the compartment member in the recess;
filling any voids between the compartment member and the sport element with additional polymeric mixture to form a smooth transition from an upper surface of the sport element to an upper surface of the compartment member; and
curing the polymeric mixture and the additional polymeric mixture, thereby forming a smooth and hard interface between the compartment member and the sport element.

17. A method of using a high-performance portable electronic system, comprising:
providing a high-performance portable electronic system, the high-performance portable electronic system providing step comprising:
providing a portable electronic device; and
providing a compartment member for accommodating the portable electronic device,
wherein the compartment member providing step comprises providing compartment member as being removably installable into a sport element selected from a group consisting essentially of a sporting good and a sport garment, the sport element having a surface,
wherein the portable electronic device providing step comprises providing the portable electronic device as being removably installable in the compartment member, and
wherein the portable electronic device providing step and the compartment member providing step, together, comprise providing the portable electronic device and providing the compartment member as being contiguously disposable with the surface; and
disposing the portable electronic device in the compartment member.

18. The method of claim 17, further comprising:
providing a cover member for closing the compartment member when the portable electronic device is removed from the compartment member, wherein the cover member providing step and the compartment member providing step, together, comprise providing the cover member and providing the compartment member being contiguous with the surface; and
providing a watchband.

19. The method of claim 18, further comprising:
removing the portable electronic device from the compartment member; and
disposing the cover member in the compartment member.

20. The method of claim 18, further comprising coupling the portable electronic device with the watchband.
